(19) United States
(12) Patent Application Publication
(10) Pub. No.: US 2003/0018982 A1
(43) Pub. Date: Jan. 23, 2003

(54) Adjustable video frequency response filter for a set-top terminal

(75) Inventors: David Eric Zeidler, Warrington, PA (US); Joseph A. Petry, Philadelphia, PA (US); Mathias Anton Muller, Line Lexington, PA (US)

Correspondence Address: RADER FISHMAN & GRAUER PLLC, LION BUILDING, 1233 20TH STREET N.W., SUITE 501, WASHINGTON, DC, 20036, US

(73) Assignee: General Instrument Corporation

(21) Appl. No.: 09/909,978

(22) Filed: Jul. 23, 2001

(51) Int. Cl. H04N 7/173; H04N 7/16; H04N 5/50

(52) U.S. Cl. 725/151; 348/735; 725/139; 725/131

(57) ABSTRACT

A system and method for adjusting a video frequency response of a set-top terminal using a video frequency response filter. The video frequency response filter is included in a video processing subsystem. The video frequency response filter adjusts the video frequency response of the set-top terminal by using a set of filter coefficients determined by a microprocessor subsystem. The set of filter coefficients can be determined by various methods. One method is by measuring the frequency response degradation of the set-top terminal without the video frequency response filter installed in the set-top terminal. Another method is to measure the amplitude of a color burst signal included in the video input signal. Yet another method is to measure the amplitudes of a multi-burst signal included in the video input signal. The invention compensates for imperfections in the set-top circuit components and enables the set-top terminal to consistently meet the specification requirements for channel flatness without increasing the cost of the components.

### BACKGROUND OF THE INVENTION

1. Field of the Invention

This invention generally relates to cable television (CATV) communication systems, and in particular to a CATV set-top terminal that includes an adjustable video frequency response filter to compensate for imperfections in the set-top circuit components and enable the set-top terminal to consistently meet the specification requirements for frequency response flatness of each channel.

2. Description of the Related Art

The Federal Communications Commission (FCC) specification for channel flatness directly relates to the set-top terminal parametric of video frequency response as to how flat in frequency response the set-top terminal passes the video signal. Specifically, the FCC specification states:

“The amplitude characteristic shall be within a range of ±2 decibels from 0.75 MHz to 5.0 MHz above the lower boundary frequency of the cable television channel, referenced to the average of the highest and lowest amplitudes within these frequency boundaries,” (47 CFR 76.605 (a)(6)).

There are several components and subsystems in the set-top terminal that can degrade the flatness including the tuner, channel Surface Acoustic Wave (SAW) filter, Intermediate Frequency (IF) amplifiers, video SAW filter, video demodulator/descrambler and remodulator. These components are affected by design and manufacturing limitations, part-to-part tolerances, temperature coefficients and aging.

One approach to solve the problem is to tighten component design, material, and manufacturing limitations. However, this approach increases the manufacturing cost of the components used in the set-top terminal.

The inventors of the present invention have recognized the problem with this approach and have developed a system and method that includes an adjustable video frequency response filter to compensate for imperfections in the set-top circuit components and enables the set-top terminal to consistently meet the specification requirements for channel flatness.

### SUMMARY OF THE INVENTION

One aspect of the invention is to compensate for frequency response degradation with a video digital filter to improve the performance specification of the video frequency response of the set-top terminal. Alternatively, the degradation can be measured or gauged, and then compensated in a feed-forward type technique.

The set-top terminal of the invention comprises a tuner for receiving a video input signal, a video demodulator/descrambler for receiving the video input signal from the tuner, and a video processing subsystem for receiving the video input signal from the video demodulator/descrambler. The video processing subsystem includes a video decoder, and a video frequency response filter for adjusting a frequency response of the set-top terminal.

A method for adjusting a frequency response of a set-top terminal comprising the steps of:

providing a video input signal to a set-top terminal, the set-top terminal including a video processing subsystem, a microprocessor subsystem, and a memory, the video processing subsystem including a video frequency response filter; and

adjusting a frequency response of the set-top terminal using the video frequency response filter.

### BRIEF DESCRIPTION OF THE DRAWINGS

In the drawings:

FIG. 1 shows a block diagram of a set-top terminal incorporated an embodiment of the invention;

FIG. 2 shows a Vertical Blanking Interval (VBI) portion of a standard NTSC analog television signal, including the Vertical Interval Test Signal (VITS) area;

FIG. 3 shows a graph of frequency response of a video Surface Acoustic Wave (SAW) filter as a function of temperature;

FIG. 4 shows a plot of a color burst signal and horizontal sync included in a video input signal; and

FIG. 5 shows a plot of a multi-burst test signal that may be included in a video input signal.

### DESCRIPTION OF THE PREFERRED EMBODIMENT

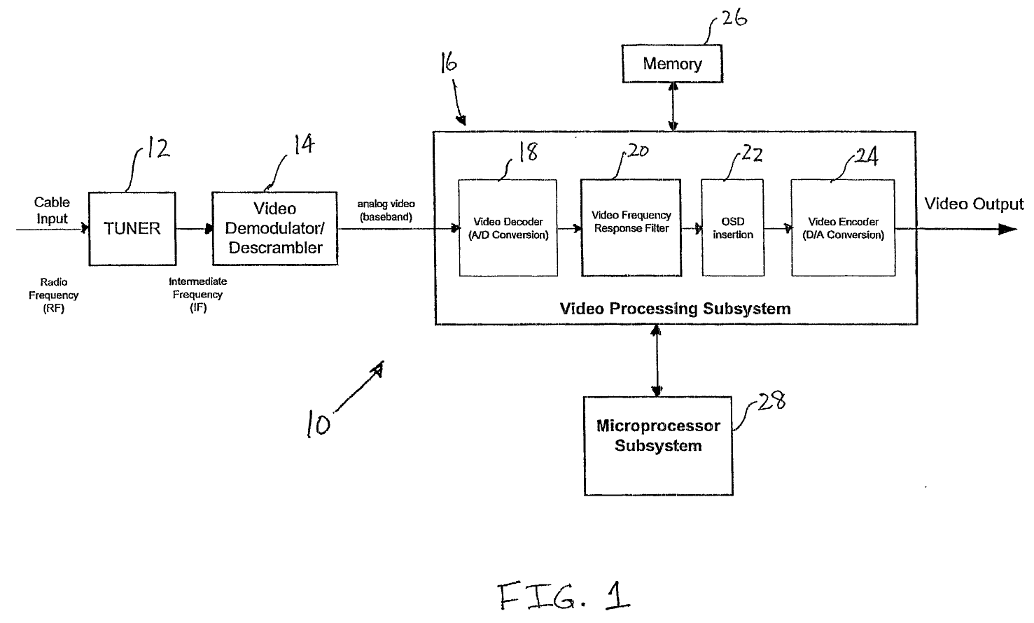

Referring now to FIG. 1, a set-top terminal 10 of the invention includes a tuner 12 that receives a radio frequency (RF) input signal from the cable supplier. The tuner 12 provides an intermediate frequency (IF) signal to a video demodulator/descrambler 14 that processes the IF video signal into an analog video signal, otherwise known as a baseband video signal, in a conventional manner.

The analog baseband video signal from the video demodulator/descrambler 14 is provided to a video processing subsystem, shown generally at 16. The video processing subsystem 16 includes a video decoder 18 that decodes and converts the analog baseband video signal to a digital video signal. A video frequency response filter 20 receives the decoded digital signal from the video decoder 18. The purpose of the video frequency response filter 20 is discussed in more detail below. An On-Screen Display (OSD) insertion 22 receives the digital video signal from the video frequency response filter 20 and adds text/graphics, for example, a program guide that is overlaid on the video content. A video encoder 24 receives the digital video signal from the OSD insertion 22 and converts the digital signal into an analog video output signal for display in a conventional manner on a display device (not shown), for example, a television. Those skilled in the art will appreciate that the invention may also be implemented as a stand-alone device adapted to receive a television (or other video or multimedia) signal, e.g., from a set-top terminal. In the alternative, the device functionality may be included as part of a television, a personal versatile recorder (PVR), a personal computer, a personal digital assistant (PDA), or similar device (either wired or wireless) having the capability to receive and decode a video signal.

The set-top terminal 10 may also include a memory 26 of a conventional type coupled to the video processing subsystem 16 for temporarily storing the video signal being processed by the video processing subsystem 16. In addition, the set-top terminal 10 may include a microprocessor subsystem 28 of a conventional type coupled to the video processing subsystem 16 for performing measurements and calculations on the video signal. Although the memory 26 and microprocessor subsystem 28 are illustrated as separate components, it will be appreciated that the memory 26 and/or the microprocessor subsystem 28 can be integrated into the video processing subsystem 16.

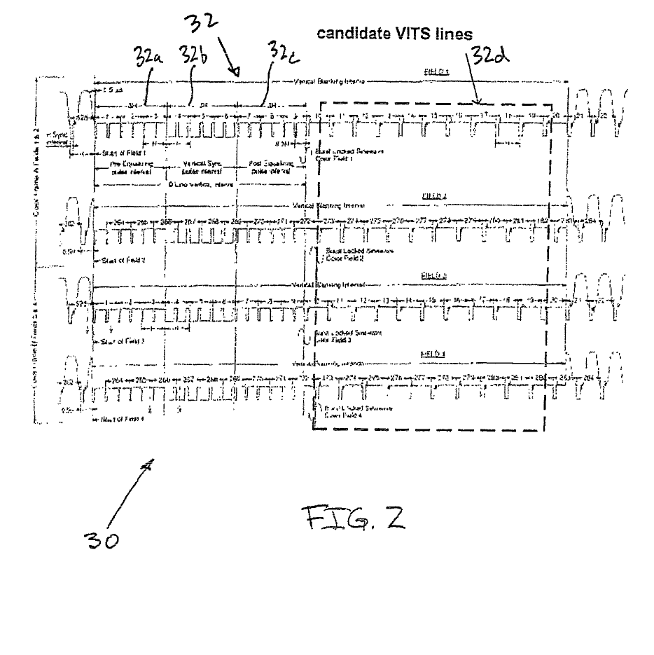

Referring now to FIG. 2, the video signal processed by the video processing subsystem 16 may contain analog vertical interval test signal (VITS), shown generally at 30, in accordance with the National Television Systems Committee (NTSC) standard well-known in the art. Typically, one full frame of video comprises four fields designated as FIELD1, FIELD2, FIELD3 and FIELD4. Typically, FIELD1 and FIELD2 comprise a color frame “A” portion of the video signal 30, and FIELD3 and FIELD4 comprise a color frame “B” portion of the video signal 30. A portion of each FIELD1, FIELD2, FIELD3 and FIELD4 comprises a vertical blanking interval (VBI) 32 that includes a pre-equalizing pulse interval 32a, a vertical sync pulse interval 32b, a post-equalizing pulse interval 32c, and a candidate VITS interval 32d. For brevity, only FIELD1 of the VBI 32 will be discussed below because the VBI 32 is identical for each FIELD1, FIELD2, FIELD3 and FIELD4.

One aspect of the invention is to compensate for imperfections in the set-top circuit components and enable the set-top terminal 10 to consistently meet the specification requirements for channel flatness. One component that may provide a source of frequency response degradation in the set-top terminal 10 is a video Surface Acoustic Wave (SAW) filter that is incorporated into the video demodulator/descrambler 14 (FIG. 1). One purpose of the video SAW filter is to separate the video carrier signal from the audio carrier signal. Typically, this is accomplished by applying a Vestigal Side Band (VSB) slope and passing the video (flat frequency transfer) signal beyond the VSB slope while attenuating the audio carrier signal that resides at 4.5 MHz from the video carrier signal.

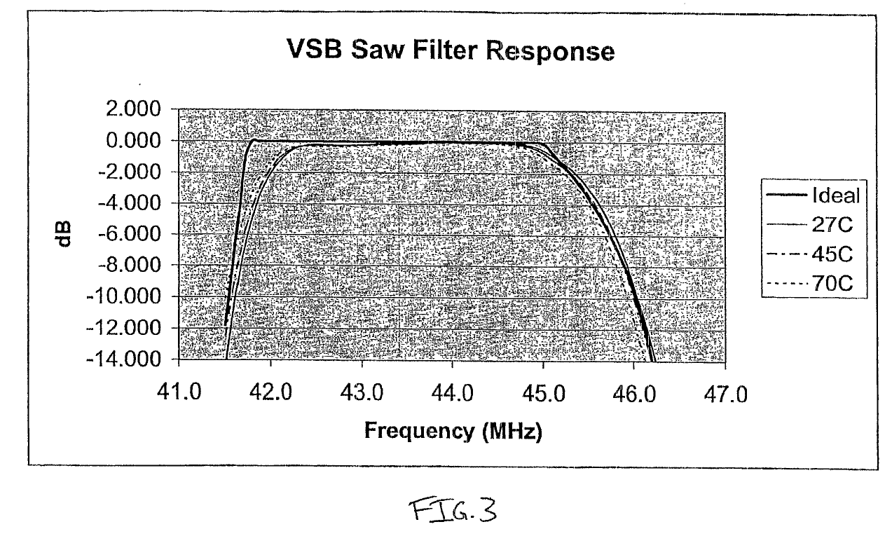

Referring now to FIG. 3, the frequency response for an ideal video SAW filter and a typical set of frequency response curves for a video SAW filter as a function of temperature are illustrated. As shown in FIG. 3, the frequency response of the video SAW filter can be seen to be non-ideal in its nominal shape and can be more than 2 dB different than the ideal SAW filter frequency response. In addition, the frequency response of the video SAW filter as a function of temperature may have a temperature drift of almost 2 dB. Further, part-to-part variations can exhibit different shapes and frequency centers. Because the frequency response of the video SAW filter directly relates to the video frequency response of the set-top terminal 10, the frequency response of the video SAW filter can cause the set-top terminal 10 to be in non-compliance with the specifications required by the FCC. It will be appreciated that the video SAW filter is an example of only one component or subsystem that can be compensated by the adjustable video frequency invention.

In order to compensate for the frequency response of a video SAW filter, as well as for other components in the set-top terminal 10, the invention incorporates the video frequency response filter 20 in the video processing subsystem 16 of the set-top terminal 10. Specifically, the video frequency response filter 20 can be programmed by the microprocessor subsystem 28 with a predetermined set of Finite Impulse Response (FIR) filter coefficients that will compensate for the frequency response degradation due to any component in the set-top terminal 10.

The FIR filter coefficients can be determined by using a variety of methods. One method is to perform empirical measurements of the frequency response degradation of the set-top terminal 10 without the video frequency response filter 20 installed in the set-top terminal 10. Once the frequency response degradation of the set-top terminal 10 is determined, the video frequency response filter 20 can be pre-programmed with the predetermined set of FIR filter coefficients to compensate for the frequency response degradation of the set-top terminal 10. It should be noted that the empirical measurements to determine the frequency response degradation should be performed prior to placing the set-top terminal 10 into service.

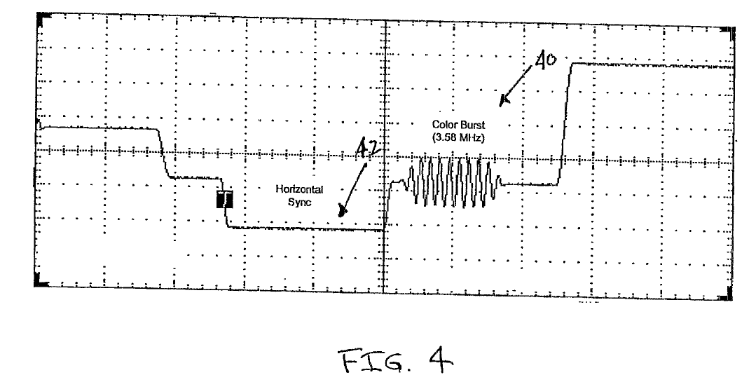

Another method in which the FIR filter coefficients can be determined by the microprocessor subsystem 28 is by measuring the relative amplitude between a color burst signal 40 and a horizontal sync 42 received from the video decoder 18, as shown in FIG. 4. The amplitude of the color burst signal can be calculated by the microprocessor subsystem 28 at a single video frequency of approximately 3.58 MHz for video lines 10 through 262 (FIG. 2). With this information, and any prior knowledge of the expected shape of the frequency response degradation, the microprocessor subsystem 28 can calculate a frequency response curve (or set of points) that will best correct the frequency response degradation of the set-top terminal 10. From this set of points, the microprocessor subsystem 28 determines and sets the FIR filter coefficients in the video frequency response filter 20.

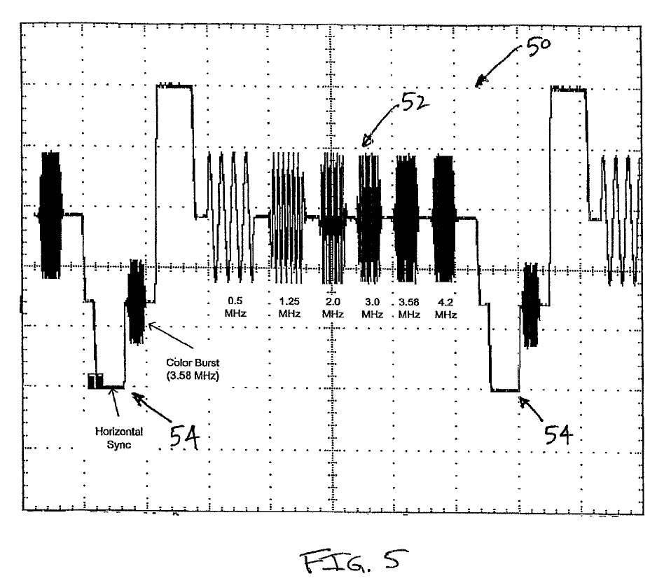

Yet another method in which the FIR filter coefficients can be determined by the microprocessor subsystem 28 is by including a video test signal in one of the video lines that are not displayed by the display device. For example, the video test signal can be included in the candidate VITS interval 32d (video lines 10 through 20 in FIG. 2). The video test signal included in one of the video lines of the VITS 30 may be, for example, a multi-burst test signal, shown generally at 50 in FIG. 5.

In this method, the set-top terminal 10 is tuned to an analog channel that contains the multi-burst test signal 50 and the microprocessor subsystem 28 retrieves one line of video from the memory 26. The microprocessor subsystem 28 then measures an amplitude of each burst (the bursts are at different video frequencies), shown generally at 52 in FIG. 5. It should be noted that the multi-burst signal 50 illustrated in FIG. 5 is an ideal multi-burst signal. In reality, the amplitudes of each burst in the multi-burst signal 50 are not substantially identical because of the frequency response degradation due to the circuit components in the set-top terminal 10. To determine the set of filter coefficients for the video frequency response filter 20, the microprocessor subsystem 28 scales the measured amplitude of each burst with respect to the horizontal sync level 54. Then, the microprocessor subsystem 28 calculates a frequency response curve (or set of points) that will best correct the frequency response degradation of the set-top terminal 10. From this set of points, the microprocessor subsystem 28 determines and sets the FIR filter coefficients in the video frequency response filter 20. It should be noted that this method can be achieved while the set-top terminal is in-use by having the microprocessor subsystem 28 determine whether the multi-burst signal 50 was present in the VITS 30 by retrieving and analyzing the candidate VITS interval 32d video lines. Because of the higher accuracy in determining the FIR coefficients as compared to the earlier-mentioned methods, this method is the preferred method of determining the FIR coefficients for the video frequency response filter 20.

It is advantageous to measure the relative amplitude between the color burst and multi-burst signals 40, 50 and the horizontal syncs 42, 54 because the overall amplitude of the video signal into the video decoder 18 may be slightly low or high due to several factors, including the headend modulator adjustment and the set-top circuitry preceding the video decoder 18. For instance, if the overall video signal is slightly too large, then the color burst and each packet of the multi-burst will also be slightly too large. In reality, however, the color burst signal 40 and each packet of the multi-burst signal 50 is too large not because of frequency response degradation, but because the overall signal amplitude is too large. In this event, the correction for the overall signal amplitude being slightly too large using the adjusted frequency response filter 20 would be undesirable. In the invention, the overall signal amplitude uncertainty is removed by measuring and comparing the relative amplitude of the color burst signal 40 and each packet of the multi-burst signal 50 with the amplitudes of the horizontal syncs 42, 54, respectively.

It will be appreciated that the invention is compatible with virtually all types of video test signals, a wide variety of which are known in the art. It will also be appreciated that the FIR filter coefficients can be stored in the memory 26. In this instance, the stored FIR filter coefficients may be accessed from a remote location, such as a cable television headend (not shown). Remote access may be provided by any suitable means, such as a cable or wireless return path, telephone return line, or the like. Further, the stored remotely accessed FIR filter coefficients may be downloaded at the remote location from the memory 26.

While the invention has been specifically described in connection with certain specific embodiments thereof, it is to be understood that this is by way of illustration and not of limitation, and the scope of the appended claims should be construed as broadly as the prior art will permit.

What is claimed is:

1. A set-top terminal, comprising:
a tuner for receiving a video input signal;
a video demodulator/descrambler decoder for receiving the video input signal from the tuner; and
a video processing subsystem for receiving the video input signal from the video demodulator/descrambler, the video processing subsystem including a video frequency response filter for adjusting a frequency response of the set-top terminal.

2. The set-top terminal according to claim 1, further including a microprocessor subsystem operatively coupled to the video processing subsystem, the microprocessor subsystem determining a set of filter coefficients for the video frequency response filter.

3. The set-top terminal according to claim 2, wherein the set of filter coefficients comprises a set of Finite Impulse Response (FIR) filter coefficients.

4. The set-top terminal according to claim 3, wherein the FIR filter coefficients are determined by empirical measurements of a degradation of the frequency response of the set-top terminal prior to installation of the video frequency response filter.

5. The set-top terminal according to claim 3, wherein the FIR filter coefficients are determined by measuring an amplitude of a color burst signal included in the video input signal.

6. The set-top terminal according to claim 3, wherein the FIR filter coefficients are determined by measuring an amplitude of a multi-burst signal included in the video input signal.

7. The set-top terminal according to claim 6, further including a memory for temporarily storing at least a portion of the input video signal for measuring the amplitude of the multi-burst signal by the microprocessor subsystem.

8. A method for adjusting a frequency response of a set-top terminal, comprising the steps of:
receiving a video input signal using a tuner;
receiving the video input signal from the tuner using a video demodulator/descrambler decoder; and
receiving the video input signal from the video demodulator/descrambler using a video processing subsystem, the video processing subsystem adjusting a frequency response of the set-top terminal using a video frequency response filter.

9. The method according to claim 8, further including the step of determining a set of filter coefficients for the video frequency response filter using a microprocessor subsystem operatively coupled to the video processing subsystem.

10. The method according to claim 9, wherein the set of filter coefficients comprises a set of Finite Impulse Response (FIR) filter coefficients.

11. The method according to claim 10, wherein the FIR filter coefficients are determined by empirical measurements of a degradation of the frequency response of the set-top terminal prior to installation of the video frequency response filter.

12. The method according to claim 10, wherein the FIR filter coefficients are determined by measuring an amplitude of a color burst signal included in the video input signal.

13. The method according to claim 10, wherein the FIR filter coefficients are determined by measuring an amplitude of a multi-burst signal included in the video input signal.

14. The method according to claim 13, further including the step of temporarily storing at least a portion of the input video signal for measuring the amplitude of the multi-burst signal by the microprocessor subsystem.

15. A method for adjusting a frequency response of a set-top terminal, comprising the steps of:
providing a video input signal to a set-top terminal, the set-top terminal including a video processing subsystem, a microprocessor subsystem, and a memory, the video processing subsystem including a video frequency response filter; and
adjusting a frequency response of the set-top terminal using the video frequency response filter.

16. The method according to claim 15, wherein the video frequency response filter uses a set of filter coefficients determined by a microprocessor subsystem operatively coupled to the video processing subsystem to adjust the frequency response of the set-top terminal.

17. The method according to claim 16, wherein the set of filter coefficients are determined by empirical measurements.

18. The method according to claim 16, wherein the filter coefficients are determined by measuring an amplitude of a color burst signal.

19. The method according to claim 16, wherein the filter coefficients are determined by measuring an amplitude of a multi-burst signal.
